(19) United States
(12) Patent Application Publication
(10) Pub. No.: US 2026/0343817 A1
(43) Pub. Date: Oct. 29, 2026

(54) TWO-PHASE HEAT EXCHANGER FOR HIGH-HEAT FLUX CHIP SETS

(71) Applicant: Mikros Technologies LLC, Claremont, NH (US)

(72) Inventor: David Fogg, Enfield, NH (US)

(73) Assignee: Mikros Technologies LLC, Claremont, NH (US)

(21) Appl. No.: 19/155,323

(22) PCT Filed: Jan. 8, 2025
(86) PCT No.: PCT/US2025/010780

§ 371 Date: Aug. 11, 2025

Related U.S. Application Data
(60) Provisional application No. 63/619,654, filed on Jan. 10, 2024.

(51) Int. Cl. H05K 7/20

(52) U.S. Cl. CPC H05K 7/20327

(57) ABSTRACT

A two-phase heat exchanger includes a manifold assembly configured to have an input manifold for fluid inlet flow and an output manifold for two-phase output flow, and a heat transfer matrix coupled to the manifold assembly. The heat transfer matrix includes a plurality of microchannels that are in fluid communication with the input manifold and the output manifold. Each of the plurality of microchannels includes a flow restriction configured to inhibit redistribution of fluid inlet flow and balance pressure drop between certain ones of the plurality of microchannels. Pairs of the plurality of microchannels are in a counterflow configuration with an inlet of a microchannel adjacent to an outlet of a neighbor microchannel, where the counterflow configuration increases packing density and reduces pressure drop in the heat transfer matrix.

### TECHNICAL FIELD

This disclosure relates to heat exchangers, and more particularly, to two-phase cold plates that include flow restrictors and counterflow diverging channel geometries to passively limit flow redistribution.

### BACKGROUND

Semiconductor devices in data centers or supercomputers generate a significant amount of heat during operation and require cooling. The transistors and active components on the semiconductor of the central processing unit (CPU) or graphical processing unit (GPU) of a computer or server consume a significant amount of electricity, which is dissipated as heat, and requires active cooling to keep the active semiconductor device temperature below the rated maximum temperature. For example, silicon semiconductor devices generally have maximum operating temperature limits between 80 °C and 95 °C, while silicon carbide semiconductor devices have maximum operating temperatures of approximately 175 °C. Above these respective rated maximum temperatures, semiconductor devices become more likely to malfunction, so effective cooling is needed to ensure the proper operation of a data center or supercomputer to avoid this from occurring.

The U.S. Department of Energy (DOE) has recognized the need to overcome technology barriers associated with the development of high-performance energy efficient cooling solutions for data centers and has announced up to $42 million in funding to find a resolution to the problem. According to the DOE, data centers that are used to house computers, storage systems, and computing infrastructure, account for approximately 2% of total U.S. electricity consumption while data center cooling can account for up to 40% of data center energy usage overall. Reducing the amount of energy data centers use for cooling will help to lower the operational carbon footprint associated with powering and cooling data centers.

The most common form of cooling today in data centers utilizes air as the coolant. Cold air is forced into a cooling device, known as a heat sink, by a fan and heats up as it removes the heat. This hot air is then cooled by a heat rejection device that removes the heat from the air and rejects it to the ambient air outside the data center. These heat rejection devices can be, for example, a radiator, a water-cooling tower, or a compressor/chiller. The heat sink which attaches to the CPU/GPU is made of a conductive material, generally aluminum or copper, and has fins that stretch away from the CPU/GPU surface. These fins increase the surface area for which the device can transfer heat into the air and improve the heat rejection performance. These heat sinks are attached to the silicon using a thermal interface material (e.g., a thermally conductive grease or thermally-conductive compliant pad), that creates a low-resistance thermal bond between the silicon and the heat sink. These thermal interface materials are needed as the surface of both the silicon and heat sink are not perfectly flat, and air gaps between the two devices would lead to large thermal resistances, and poor cooling performance.

Supercomputers or data centers which perform more intense calculations, often referred to as “high performance computing,” cannot be effectively cooled by air, as the heat loads in the CPU/GPUs are much higher than in a traditional data center. For these applications, single phase liquid coolants are used to remove the heat directly from the CPU/GPU. Conventionally, a water block or cold plate is mounted directly to the CPU/GPU into which cold water is pumped and hot water exits. The hot water is then cooled back down by a heat rejection device which dissipates that heat to the outside ambient air.

The semiconductor industry projects that within the next 5 years, future server chip sets will generate up to 200% more heat per unit area than current devices. For example, state-of-the art graphics processing units such as the H100 GPU by NVIDIA features 80 billion transistors and two types of cores that are designed to be up to 9 times faster than its predecessors. At maximum performance, the H100 outputs over 1100W at an average heat flux of 125 W/cm² over the processor core. However, the next generation device is forecasted to output over 4,000W at an average heat flux of 235W/cm². This marked increase in total power and power density is expected to test the limit of single-phase liquid cooling as the increased flow rates approach microchannel erosion limits and increase pumping power requirements.

The above options are currently deployed in high performance computing (HPC) data centers with varied success on the current generation of CPU/GPUs. However, two factors make the above cooling technologies insufficient for tomorrow's needs. First, CPU/GPUs will generate significantly more heat, increasing the demands on the cooling system's performance. Second, data centers are required to be more energy efficient, and new guidelines will mean the cooling system will need to remove more heat while using less electricity in doing so. These two compounding factors mean that cooling systems of the future will need to reduce the thermal resistance, lower pumping power consumption, and improve overall cooling performance to meet the needs of next-generation semiconductor devices.

Modern data centers currently employ single-phase cold plates as the state-of-the-art solution to remove waste heat from the high performance, high-power computational and graphical processing units. Single-phase liquid cooling uses the sensible heat capacity of the liquid to store and transport heat. Single-phase liquid cold plates have low thermal resistances, but require significant flow rates, large temperature differences between the incoming flow and the working surface, or a combination thereof to remove large amounts of heat.

As power levels continue to rise, the increased flow rates and approach temperature requirements associated with single-phase cooling will face practical limits. Two-phase flow in microchannels has shown promise as the next logical approach to cooling next generation semiconductor devices. Two-phase cold plates leverage the latent heat of phase change to absorb heat by vaporizing liquid coolant, in whole or in part, to its vapor phase. As latent heats are often orders of magnitude larger than the sensible heat capacity of single-phase liquid, two-phase flow rates are often substantially reduced relative to single phase alternatives, resulting in energy savings with regards to pumping power. However, two-phase microchannel heat sinks are prone to flow, pressure, and temperature oscillations, associated with but not limited to, highly non-uniform local heat flux and non-uniform local heat transfer coefficients within the channels themselves. Despite the research that has been performed to date, and continues to be done, there remains challenges that need to be overcome before wide-spread adoption of the technology.

Prior art disclosures regarding two-phase microchannels cold plates place microchannels in close proximity to an actively heated surface where a working fluid is boiled to remove heat. Two-phase microchannel cold plates have not been widely adopted in the industry due primarily to instability and difficulties with flow redistribution management. Unlike single-phase flow, where higher heat loads decrease fluid viscosity and increase flow rates to channels with the higher heat loads, two-phase flow generates vapor, thereby increasing pressure drop in those channels, which in turn forces liquid into the channels with lower heat loads. This negative feedback mechanism, inherent to the two-phase physics, causes the flow to redistribute in an undesirable way degrading the performance of many prior-art two-phase cold plate designs.

### SUMMARY

Described is a two-phase heat exchanger. In implementations, a two-phase heat exchanger includes a manifold assembly configured to have an input manifold for fluid inlet flow and an output manifold for two-phase output flow, and a heat transfer matrix coupled to the manifold assembly. The heat transfer matrix includes a plurality of microchannels that are in fluid communication with the input manifold and the output manifold. Each of the plurality of microchannels includes a flow restriction configured to inhibit redistribution of fluid inlet flow and balance pressure drop between certain ones of the plurality of microchannels. In implementations, pairs of the plurality of microchannels are in a counterflow configuration with an inlet of a microchannel adjacent to an outlet of a neighbor microchannel, where the counterflow configuration increases packing density and reduces pressure drop in the heat transfer matrix.

### BRIEF DESCRIPTION OF THE DRAWINGS

The disclosure is best understood from the following detailed description when read in conjunction with the accompanying drawings. It is emphasized that, according to common practice, the various features of the drawings are not to scale. On the contrary, the dimensions of the various features are arbitrarily expanded or reduced for clarity.

FIG. 1 is a perspective view of a two-phase heat exchanger in accordance with the present teachings.

FIG. 2 is a partially exploded of the two-phase heat exchanger shown in FIG. 1 in accordance with the present teachings.

FIG. 3 is a perspective view of the two-phase heat exchanger of FIG. 1 attached to a semiconductor device in accordance with the present teachings.

FIG. 4 is a partially exploded of the two-phase heat exchanger with the attached semiconductor device shown in FIG. 3 in accordance with the present teachings.

FIG. 5 is an enlarged view in partial cross-section illustrating internal flow pathways within the two-phase heat exchanger of FIG. 2 in accordance with the present teachings.

FIG. 6 is a top plan cross-sectional view of a manifold spacer layer in accordance with the present teachings.

FIG. 7 is a top plan cross-sectional view of a manifold distribution layer in accordance with the present teachings.

FIG. 8 is a top plan cross-sectional view of a port layer that accesses inlet and outlet regions of heat transfer channels in accordance with the present teachings.

FIG. 9 is a top plan cross-sectional view of a heat transfer channel layer with counterflow, expanding microchannels in accordance with the present teachings.

FIG. 10 is a schematic showing alternative expanding channel profiles in accordance with the present teachings.

FIG. 11 is a schematic depicting a typical spatial relationship between high bandwidth memory (HBM) and a CPU/GPU core for a server chip set.

FIG. 12 is a diagram for a two-phase heat exchanger for cooling a single heat generating region comprising a first flow path layout in accordance with the present teachings.

FIG. 13 is a diagram of a two-phase heat exchanger for cooling a multi-zoned heat generating region comprising a second flow path layout with minimal flow redistribution in accordance with the present teachings.

### DETAILED DESCRIPTION

Reference will now be made in greater detail to embodiments, examples of which are illustrated in the accompanying drawings. Wherever possible, the same reference numerals will be used throughout the drawings and the description to refer to the same or like parts.

As used herein, the terminology “determine” and “identify,” or any variations thereof includes selecting, ascertaining, computing, looking up, receiving, determining, establishing, obtaining, or otherwise identifying or determining in any manner whatsoever using one or more of the devices and methods are shown and described herein.

As used herein, the terminology “example,” “the embodiment,” “implementation,” “aspect,” “feature,” or “element” indicates serving as an example, instance, or illustration. Unless expressly indicated, any example, embodiment, implementation, aspect, feature, or element is independent of each other example, embodiment, implementation, aspect, feature, or element and may be used in combination with any other example, embodiment, implementation, aspect, feature, or element.

As used herein, the terminology “or” is intended to mean an inclusive “or” rather than an exclusive “or.” That is, unless specified otherwise, or clear from context, “X includes A or B” is intended to indicate any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from the context to be directed to a singular form.

As used herein, unless explicitly stated otherwise, any term specified in the singular may include its plural version. For example, “a computer that stores data and runs software,” may include a single computer that stores data and runs software or two computers—a first computer that stores data and a second computer that runs software. Also “a computer that stores data and runs software,” may include multiple computers that together stored data and run software. At least one of the multiple computers stores data, and at least one of the multiple computers runs software.

As used herein, unless explicitly stated otherwise, the term fluid and/or coolant fluid may refer to, but is not limited to, electronics coolant liquids containing perfluorinated compounds (PFCs), water, and/or water-glycol mixes (brines).

Further, for simplicity of explanation, although the figures and descriptions herein may include sequences or series of steps or stages, elements of the methods disclosed herein may occur in various orders or concurrently. Additionally, elements of the methods disclosed herein may occur with other elements not explicitly presented and described herein. Furthermore, not all elements of the methods described herein may be required to implement a method in accordance with this disclosure and claims. Although aspects, features, and elements are described herein in particular combinations, each aspect, feature, or element may be used independently or in various combinations with or without other aspects, features, and elements.

Further, the figures and descriptions provided herein may be simplified to illustrate aspects of the described embodiments that are relevant for a clear understanding of the herein disclosed processes, machines, and/or manufactures, while eliminating for the purpose of clarity other aspects that may be found in typical similar devices, systems, and methods. Those of ordinary skill may thus recognize that other elements and/or steps may be desirable or necessary to implement the devices, systems, and methods described herein. However, because such elements and steps do not facilitate a better understanding of the disclosed embodiments, a discussion of such elements and steps may not be provided herein. However, the present disclosure is deemed to inherently include all such elements, variations, and modifications to the described aspects that would be known to those of ordinary skill in the pertinent art in light of the discussion herein.

Two-phase instability and flow redistribution management remains one of the challenges for wide-spread industrial adoption of high-heat flux two-phase cold plate technologies. One of the primary challenges facing two-phase heat exchangers is thermofluidic instabilities that can lead to local dry-out and the associated increased thermal resistances during operation.

Described herein is a two-phase cold plate heat exchanger with reduced thermal resistance for heating or cooling high-performance computing chips sets, data center servers, automated intelligence supercomputers, power electronics, laser modules, and other high-power, high-heat flux heating or cooling applications. The teachings described herein mitigate the instability and flow redistribution management challenges found in conventional two-phase microchannel cold plates. The two-phase heat exchangers described herein provide highly effective, high cooling capacity thermal management and include design features to mitigate the effects of flow maldistribution.

In implementations, a two-phase cold plate disclosed includes a microchannel cold plate that is pressed against a heat generating device. The two-phase cold plate includes features to passively limit flow redistribution for the spatially and temporally-varying thermal loads that are common in high-performance computing applications. The teachings disclosed herein effectively shape the pressure drop versus flow rate characteristics of the cold plate to minimize unstable regions over the application operational range of the two-phase cold plate.

In implementations, a two-phase cold plate includes flow restrictions at a plurality of inlets of a microchannel array to inhibit the redistribution of flow from one channel to another, while counterflow diverging channel geometries reduce the overall pressure drop and increase packing density.

In implementations, a two-phase cold plate includes flow restrictions and diverging channel geometries and further includes mechanisms to further mitigate flow maldistribution and instability for more complex loads, i.e., those involving multiple zones, each with its own heat generation rates that may vary in both space and time, for example, a server microprocessor chip set used in data center servers that carry complex loads. Such chip sets have one or more processing cores surrounded by other regions dedicated to high bandwidth memory. This implementation employs series-parallel flow architecture with interspersed channels in the cold plate proximate to the processor core to inhibit flow redistribution over a wide range of operating conditions. The processing cores often do not behave as a monolithic entity, but rather exhibit localized hot spots within the processing footprint as different regions of the core activate to perform the various computations.

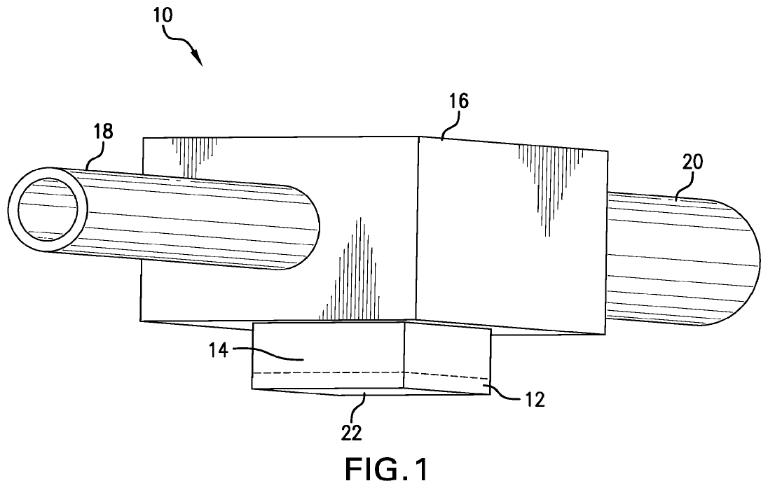

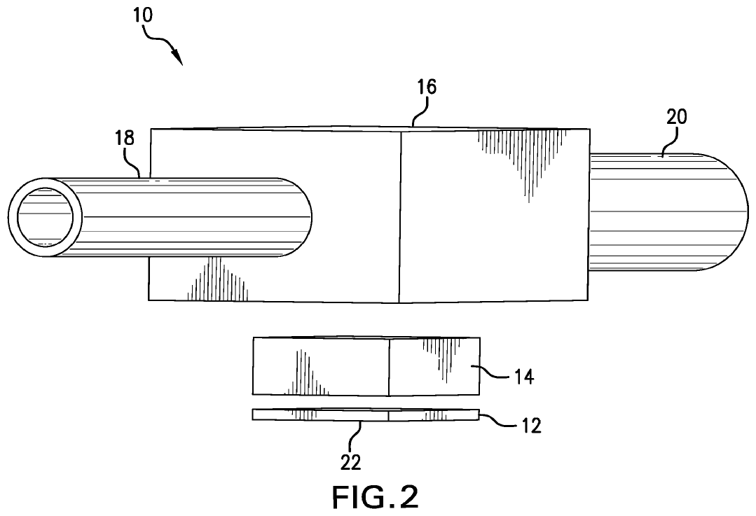

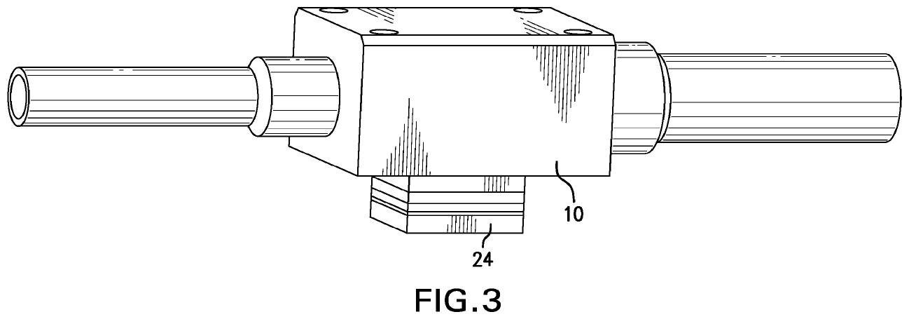

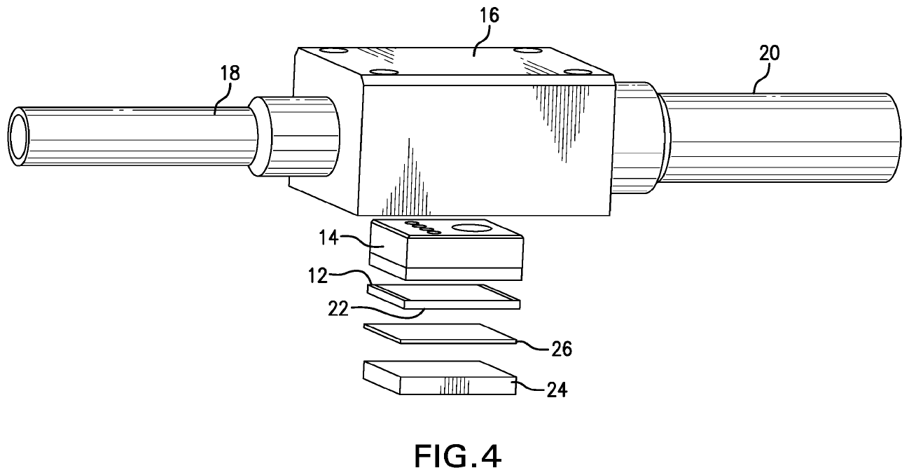

FIG. 1 is a perspective view of a two-phase heat exchanger 10 in accordance with the present teachings. FIG. 2 is a partially exploded of the two-phase heat exchanger 10 in accordance with the present teachings. FIG. 3 is a perspective view of the two-phase heat exchanger 10 attached to a semiconductor device 24 in accordance with the present teachings. FIG. 4 is a partially exploded of the two-phase heat exchanger 10 with the attached semiconductor device 24 in accordance with the present teachings.

In implementations, a two-phase heat exchanger 10 can include, but is not limited to, a heat transfer matrix or cold plate 12, a manifold assembly 14, an access header 16, at least one inlet port 18, and at least one outlet port 20. The heat transfer matrix or cold plate 12 includes a heat transfer surface 22. The heat transfer matrix or cold plate 12 is supplied by flow via the manifold assembly 14. The access header 16 links the manifold assembly 14 to the at least one inlet port 18 and at least one outlet port 20.

In implementation, the heat transfer matrix 12, the manifold assembly 14, and/or combinations thereof may include microchannel geometries, for example, as shown and described in U.S. Pat. No. 8,474,516, issued Jul. 2, 2013, titled “Heat Exchanger Having Winding Micro-channels,” assigned and/or owned by the current applicant, which is incorporated herein by reference as if set forth (the “'516 Patent”). In summary, the heat exchanger of the '516 Patent includes a heat transfer member having winding micro-channels, a manifold, and a cover plate. The micro-channels' winding design is defined by a nonlinear flow axis that has a plurality of short pitch and small amplitude undulations, which cause the flow to change directions, as well as two or more large amplitude bends that cause the flow to reverse direction. In low flow per unit area applications, the winding micro-channels allow a user to customize the pressure drop to promote good flow distribution, to achieve improved heat transfer uniformity, and to enable the pressure drop to remain above the bubble point of the heat transfer structure to prevent gas blockage. The winding micro-channels also increase the heat transfer coefficient. The heat transfer member includes one or more heat transfer layers, each having a plurality of inlet openings and corresponding outlet openings. Each of the winding micro-channels is in fluid communication with at least one of the inlet openings and at least one of the corresponding outlet openings, such that the cooling fluid enters the inlet openings, flows along the micro-channels, and exits via the outlet openings. The openings are arranged in rows through each layer, each opening extending from the first surface through to the second surface of each heat transfer layer. The manifold supplies fluid to each of the inlet openings of the heat transfer member and receives fluid from each of the outlet openings of the heat transfer member. The manifold distributes and collects the fluid throughout the active heat transfer area in order to promote uniform heat transfer throughout the area. The fluid enters the heat exchanger through an inlet port that is fluidly connected to an inlet header that distributes the fluid along the y-axis of the manifold. The fluid is then fed to inlet channels that are fluidly connected to the inlet header, such that the fluid is distributed by the inlet channels along the x-axis of the manifold. A plurality of outlet channels which are interdigitated with the inlet channels collect the exit fluid along the x axis of the manifold and carry it to the outlet header which collects the fluid along the y-axis if the manifold and carries it to the outlet port. The functions of distributing and collecting the fluid to the heat transfer surface and transferring the heat between the fluid and the surface are achieved by the manifold and the heat transfer member, respectively. This separation in functions allows the selection of the flow passage geometry in each component to the benefit of their respective functions. The configuration of the winding micro-channels can be modified according to a particular application, but in all applications, the micro-channel axis remains nonlinear.

Returning back to FIGS. 1-4, to cool a device, the heat transfer surface 22 of the heat transfer matrix 12 is pressed against a device 24 to be cooled. In implementations, a thermal interface material 26 can be placed in between the heat transfer matrix 12 and the device 24 to improve thermal contact and lower the interface thermal resistance.

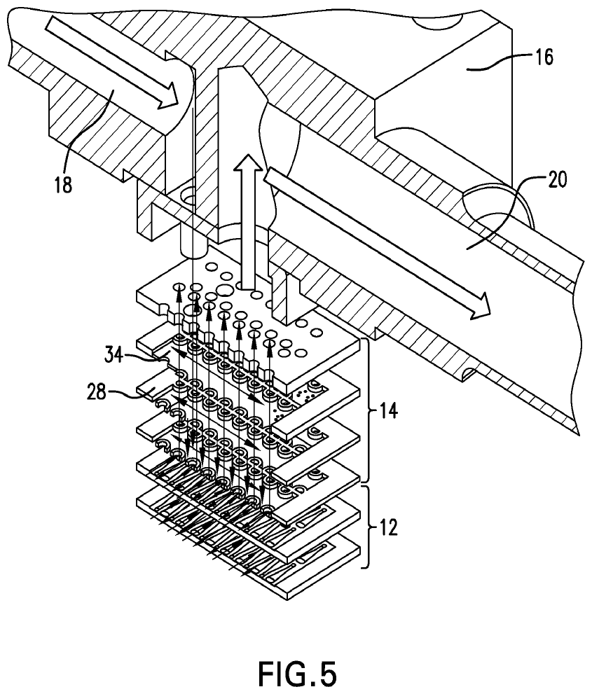

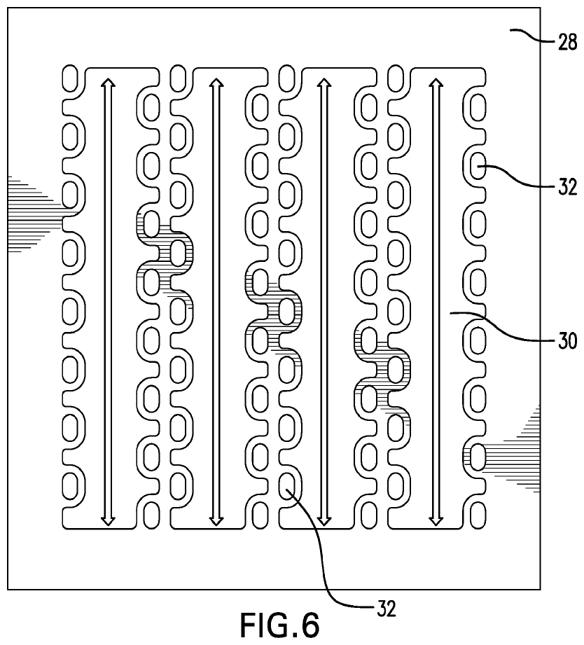

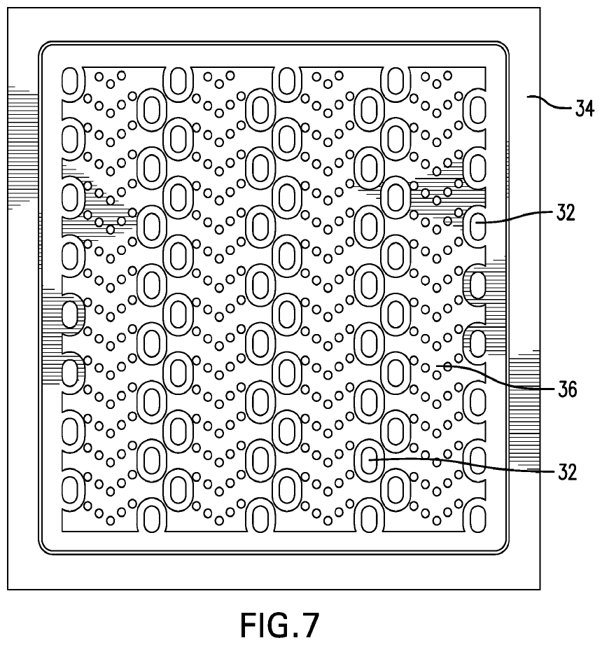

FIG. 5 is an enlarged view in partial cross-section illustrating internal flow pathways within the two-phase heat exchanger 10 in accordance with the present teachings. FIG. 6 is a top plan cross-sectional view of a manifold spacer layer and/or plate 28 in the manifold assembly 14 in accordance with the present teachings. FIG. 7 is a top plan cross-sectional view of a manifold distribution layer and/or plate 34 in the manifold assembly 14 in accordance with the present teachings.

In implementations, inlet and outlet fluid manifolds in the manifold assembly 14 can distribute flow to and receive flow from an array of parallel microchannels in the heat transfer matrix 12. The inlet and outlet fluid manifolds can be, for example, appropriate portions of the one or more manifold spacer layers and/or plates 28 and/or appropriate portions of the one or more manifold distribution layers and/or plates 34. That is, the manifold assembly 14 can include one or more manifold spacer layers and/or plates 28 and/or one or more manifold distribution layers and/or plates 34, where certain or defined areas and/or structures are used for inlet of fluid flow (inlet manifold) and certain or defined areas and/or structures are used for outlet of two-phase flow (outlet manifold). In implementations, the inlet and outlet fluid manifolds can distribute flow to a plurality of parallel arrays, as would be known to one of ordinary skill in the art. Fluid and/or coolant fluid (represented by the light grey arrows in FIG. 5) can enter the access header 16 through the inlet tube 18. The access header 16 sends the flow into a liquid side of the manifold assembly 14.

Each of the one or more manifold spacer layers and/or plates 28 in the manifold assembly 14 can provide open areas 30 for the inlet flow to spread to inlets of the microchannels located adjacent to an active heat transfer surface (e.g., heat transfer surface 22). In implementations, the inlet flow spreads laterally in a direction parallel to the heat transfer surface. The maximum lateral flow resistance in the one or more manifold spacer layers and/or plates 28 is on the order of 10% to 25% or less of the pressure drop through the microchannels of heat transfer matrix 12 to facilitate uniform mass flow distribution within the active microchannels to less than 20% variation, or more preferably less than 10%, between individual microchannels. Each of the one or more manifold spacer layers and/or plates 28 further includes holes through the lamination to create outlet passages 32 for the two-phase flow (i.e., at least vapor as represented by the darker grey arrows in FIG. 5) exiting the heat transfer matrix 12 to transit the manifold assembly 14 to avoid mixing fluidically with the inlet flow. The term two-phase flow refers to or means that the flow includes both vapor and liquid.

Each of the one or more manifold distribution layers and/or plates 34 can contain a plurality of small liquid distribution holes 36 in the region adjacent to open area or liquid lateral flow areas 30 on the one or more manifold spacer layers and/or plates 28. The smaller, liquid flow area (as represented by the plurality of small liquid distribution holes 36) through the plane of the one or more manifold distribution layers and/or plates 34 increases the resistance to flow through the manifold assembly 14 relative to the lateral flow pathways (e.g., as represented by the open areas 30) in the one or more manifold spacer layers and/or plates 28, thereby encouraging flow to distribute to all the microchannels in the heat transfer matrix 12. These liquid distribution holes 36 in the one or more manifold distribution layers and/or plates 34 are positioned such that flow from upstream passages impinges on solid regions of the one or more manifold distribution layers and/or plates 34.

In implementations, multiple manifold spacer layers and/or plates 28 can be stacked together to create taller passages with even lower lateral flow resistances, while multiple manifold distribution layers and/or plates 34 can be added to increase the through-plate flow resistance. When manifold distribution layers and/or plates 34 are employed in a single manifold assembly 14, the liquid distribution holes 36 in the manifold distribution layers and/or plates 34 are preferably offset from one another to force the flow to turn laterally before entering the distribution holes 36 on the adjacent downstream distribution plate. In implementations, the series of stacked plates can be brazed together to create the flow geometry. However, as would be known to one of ordinary skill in the art, other methods can be used to construct, arrange, and fabricate the manifold assembly 14 to achieve the required pressure drop and flow uniformity characteristics. These other methods include, but are not limited to, machined components and 3D printed manifold assemblies and are considered alternative manifold assembly embodiments.

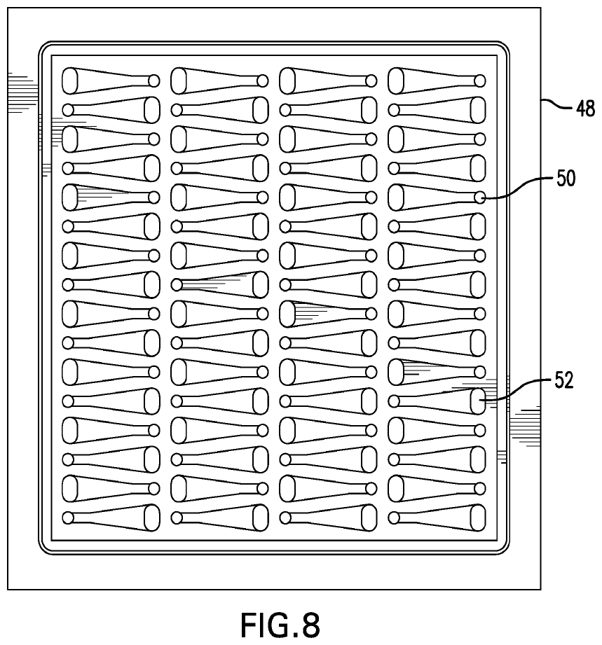

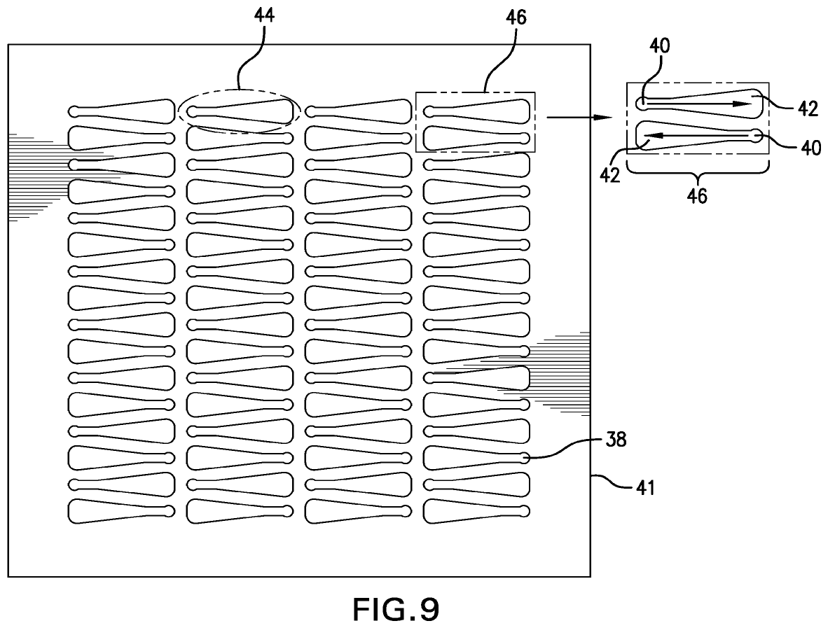

In implementations, the heat transfer matrix 12 contains a plurality of microchannels 44 and fluidic ports. These are shown with respect to FIG. 8, which is a top plan cross-sectional view of a stackable port layer 48 in the heat transfer matrix 12 that accesses inlet and outlet regions of heat transfer channels (e.g., microchannels 44) in the heat transfer matrix 12 in accordance with the present teachings, and FIG. 9, which is a top plan cross-sectional view of a heat transfer channel layer 41 in the heat transfer matrix 12 with counterflow, expanding microchannels 44 in accordance with the present teachings.

In implementations, the stackable port layer 48 can include inlet ports 50 and outlet ports 52, which are arrays of holes and/or passages that provide fluidic access from the manifold assembly(ies) 14 to inlets 40 and outlets 42 of the microchannels 44. Structure surrounding the inlet ports 50 and outlet ports 52 form conductive fins that facilitate heat spreading within the active heat transfer matrix region 12. In FIG. 8, profiles of the microchannels 44 in the adjacent layer are projected onto the stackable port layer 48 to illustrate the connectivity with the microchannels 44 in the heat transfer channel layer 41.

The microchannel geometries in the heat transfer matrix 12 include numerous features described below to address flow maldistribution within the cold plates for non-uniform heating conditions. As illustrated in FIG. 9, a flow restriction 38 is located at an inlet 40 of each microchannel 44 to help balance the pressure drop between high-heat load microchannels and lower heat load microchannels. In implementations, the flow restriction can be implemented at the inlet, across the microchannel, at the microchannel, and/or combinations thereof. Flow restrictions 38 are geometrical changes in the flow path that increase the pressure drop in those regions by increasing frictional and dynamic pressure loss characteristics. Flow restrictions 38 can be implemented using one or more of, but not limited to, reductions in channel cross-sectional area, holes, slots, orifice plates, pin fins, perforated layers, and/or combinations thereof, as would be known to one of ordinary skill in the art. In implementations, flow restrictions 38 can be used in the manifold channel geometries (e.g., in the one or more manifold spacer layers and/or plates 28 and/or one or more manifold distribution layers and/or plates 34) to further balance flow redistribution.

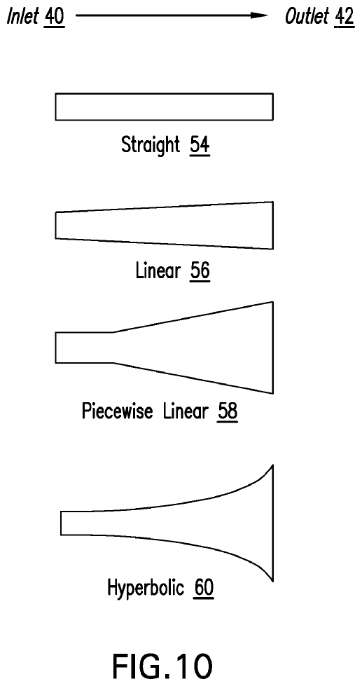

In implementations, the geometry of the microchannels and/or heat transfer channels 44 expand (termed “expanding microchannel geometry” herein), i.e., increases, from the inlet 40 to the outlet 42 to reduce pressure drops associated with the two-phase regions in the heat transfer matrix 12. The microchannel 44 transitions from a smaller cross-sectional area adjacent the inlet 40 to a larger cross-section adjacent the outlet 42 reduce the velocity of the two-phase flow. During operation, the generation of vapor in the microchannels 44 causes the flow to accelerate, which increases frictional pressure drop within the microchannels 44. The slower flow velocities associated with expanding microchannels reduce the pressure drop characteristics of the microchannels that are located in the higher vapor quality regions, resulting in more balanced flow distributions under non-uniform heating conditions. As shown in FIG. 10, the axial transition from a small cross-section adjacent the inlet 40 to large cross-sections adjacent the outlet 42 can take multiple different forms including, but not limited to, straight 54, linear 56, piecewise-linear 58, hyperbolic 60, and/or profiles that may be customized, provided that the disclosed functionality is achieved. That is, a variety of profiles for expanding microchannel geometries can be used. For high heat flux applications, the channel expansion or expanding microchannel geometry profile may be customized to the particular application based on a variety of factors including flow rate, heat loading, and packing efficiency to engineer the heat transfer and pressure drop characteristics of the cold plate for a specific application.

In implementations, the orientation for the microchannels 44 is a counterflow configuration. In a counterflow configuration, the microchannels 44 are grouped in pairs wherein the inlet 40 of each microchannel 44 is adjacent to the outlet 42 of its neighbor in the pair. The counterflow configuration increases the packing density for expanding channel geometries effectively reducing pressure drop and thermal resistance due to the increased flow and heat transfer areas. The counterflow configuration also spatially averages the non-uniform heat transfer coefficients in the two-phase microchannels 44 thereby improving temperature uniformity at the heat transfer surface 22 between the heat transfer matrix and/or cold plate 12 and the semiconductor device 24. In implementations, where lower heat fluxes are present or the layout prevents counterflow configurations, the microchannels 44 may be arranged in concurrent or crossflow configurations, as would be known to one with standard skill in the art.

In implementations, the microchannels 44 are arranged in one or more parallel arrangements. The repeating element constitutes a thermal pixel 46 that is arranged over the heat transfer matrix and/or cold plate footprint to form a microchannel array within the heat transfer matrix 12. For counterflow microchannels, the thermal pixel 46 comprises one counterflow pair. This microchannel layout utilizes a plurality of shorter microchannels to prevent excessive pressure drop in the heat transfer matrix 12, and limits variation in saturation temperature along the microchannel length. In implementations, multiple heat transfer layers (heat transfer channel layer 41 and/or stackable port layer 48) may be stacked to create a three-dimensional heat transfer matrix 12 that increases the internal heat transfer surface area and flow cross-sectional areas. Fluid and/or coolant is supplied and removed to the plurality of microchannels via the manifold assembly 14, as would be known to one of ordinary skill in the art.

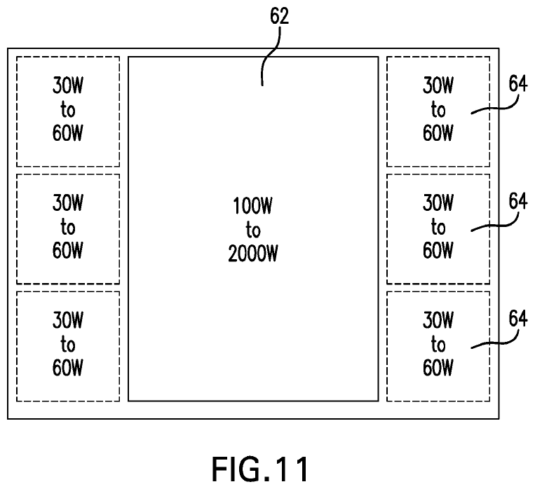

FIG. 11 is a schematic depicting a typical spatial relationship between high bandwidth memory (HBM) and a CPU/GPU core for a server chip set. High performance semiconductor chip sets often combine various functional elements (e.g. computational processing units (CPUs), graphical processing units (GPUs), high bandwidth memory (HBM), etc.) into a single chip or chip set. These functional elements are often spatially grouped into zones e.g., providing different thermal loads to the heat transfer and/or microchannels in the heat transfer matrix 12. Each zone (e.g., high-power CPU/GPUs 62 or high bandwidth memory 64) generates its own waste heat that may vary both spatially and temporally. Non-uniform thermal loading between parallel flow paths within the cold plate and/or heat transfer matrix 12 can cause flow redistribution from microchannels with higher thermal loads to microchannels with lower thermal loads unless the flow path pressure drop characteristics are reasonably balanced under the various heating states. As taught herein, each zone is cooled by microchannels specifically designed for the local heat loads. One or more manifold assemblies can connect the different zones in series, parallel, or combinations thereof, in such configurations that the two-phase heat transfer and pressure drop characteristics of the various parallel pathways are well-balanced over the expected set of operating states.

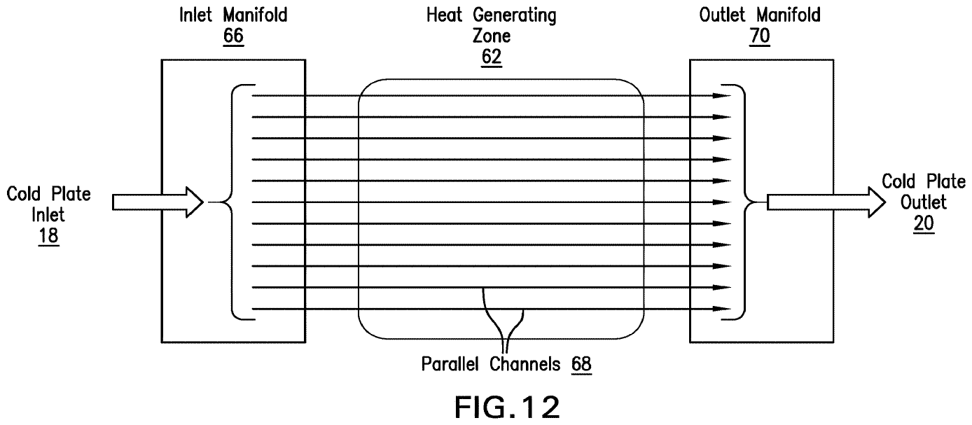

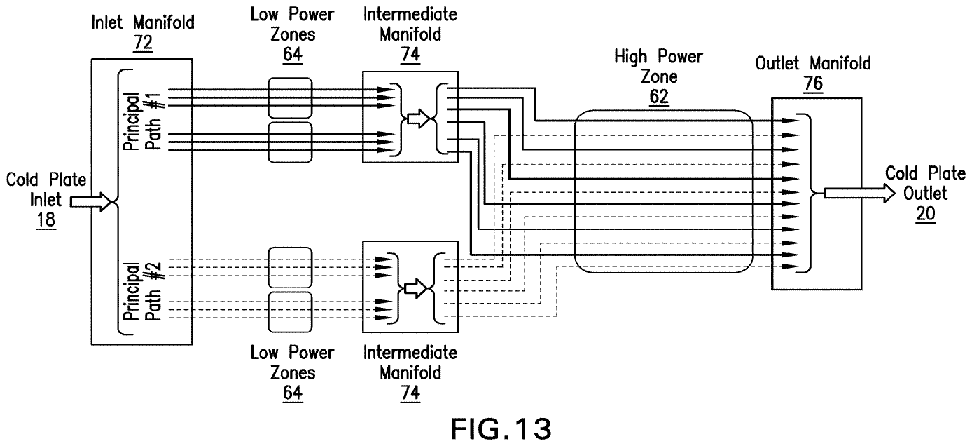

FIG. 12 is a diagram for flow connectivity for a two-phase heat exchanger for cooling a single heat generating region comprising a first flow path layout in accordance with the present teachings. In implementations, the flow connectivity shown is for a cold plate that cools a device with a single heat generating and/or functional zone 62 with a time-varying, but spatially uniform thermal load. An inlet manifold 66 splits the incoming flow into a plurality of parallel channels 68. The inlet manifold 66 and outlet manifold 70 disperse and collect flow to and from the inlet 18 and outlet 20 connections via the access header 16. This embodiment can be used in a standalone cold plate or integrated as a subassembly into a more complex flow architecture such as that shown in FIG. 13.

In many semiconductor devices, the heat output varies as a function of both time and position. This is especially true for multifunctional chips, where memory units 64 are placed near the processor core 62 as shown in FIG. 11. In such devices, memory 64 usually has lower cooling requirements compared to CPU or GPU cores. The large variation in thermal loads to the various microchannels in a purely parallel array can lead to significant flow redistribution for such multifunctional semiconductor devices.

FIG. 13 is a diagram for flow connectivity for a two-phase heat exchanger for cooling a multi-zoned heat generating region comprising a second flow path layout with minimal flow redistribution in accordance with the present teachings. In implementations, the flow connectivity shown is for use in multifunctional chips that couple high-power regions 62 (e.g., processor core 62, CPU, or GPU) with low-power zones 64 (e.g., memory 64) on a single semiconductor device. In this embodiment, the cold plate has a number of principal flow paths with nearly identical flow and thermal loading characteristics. FIG. 13 shows two principal flow paths for clarity, but there is no limit to the number of principal paths that can be employed, as would be known to one skilled in the art. Each principal flow path includes a high-power zone 62, or portion thereof, connected downstream of one or more lower power zones 64. A top-level inlet manifold 72 splits the flow into the principal pathways. Each principal flow path has parallel subarrays of cooling microchannels located over one or more of the low-power zones 64. Each principal flow path is positioned to cool a subset of the low-power zones. As the flow leaves the low-power zones 64, intermediate manifolds 74 collect and mix the flow from the plurality of channels over each low-power channel subarray. This mixing homogenizes any local heating variations within the upstream zones providing better uniformity entering subsequent zones. These intermediate manifolds 74 deliver the blended flow to the high-power region 62 located downstream. After transiting the high-power region, the high-quality vapor exiting the microchannels is collected in a top-level outlet manifold 76 connected to the cold plate outlet 18 located on the access header 16.

In implementations, both principal flow paths cool the same high-power region 62 using fluidically distinct sets of microchannel subarrays. The flow from the principal pathways communicate fluidically only at the top-level inlet manifold 72 and outlet manifold 76. Over the high-power zones 62, microchannels from the various principal flow paths are interleaved between microchannels from other alternative principal flow paths. In this interleaved arrangement, the microchannels are spatially located adjacent to one another, yet fluidically separated, ensuring that each of the principal flow paths is exposed to nearly the same thermal loading conditions even under spatially and time-varying loading conditions. This approach minimizes the variations between parallel flow paths, thereby mitigating flow maldistribution.

Described is a two-phase heat exchanger. In implementations, the two-phase heat exchanger includes a manifold assembly configured to have an input manifold for fluid inlet flow and an output manifold for two-phase output flow, and a heat transfer matrix coupled to the manifold assembly. The heat transfer matrix includes a plurality of microchannels that are in fluid communication with the input manifold and the output manifold. Each of the plurality of microchannels includes a flow restriction configured to inhibit redistribution of fluid inlet flow and balance pressure drop between certain ones of the plurality of microchannels. Pairs of the plurality of microchannels are in a counterflow configuration with an inlet of a microchannel adjacent to an outlet of a neighbor microchannel. The counterflow configuration increasing packing density and reducing pressure drop in the heat transfer matrix.

In implementations, the flow restriction is a reduction in cross-sectional area at each inlet of the plurality of microchannels. In implementations, each of the plurality of microchannels has an expanding microchannel geometry extending from the inlet configured with the flow restriction to the outlet. In implementations, a profile of the expanding microchannel geometry is based on at least one of flow rate, heat loading, and microchannel packing efficiency. In implementations, a profile of the expanding microchannel geometry is one of linear, piecewise linear, and hyperbolic. In implementations, the heat transfer matrix further includes one or more stackable port layers configured to provide fluidic access from the manifold assembly to inlets and outlets of the plurality of microchannels, and one or more heat transfer channel layers, wherein each heat transfer channel layer includes a plurality of microchannels. In implementations, the manifold assembly further includes one or more manifold spacer layers, where each manifold spacer layer defines open areas for the fluid inlet flow to spread to inlets of the plurality of microchannels, and where each manifold spacer layer defines outlet passages for the two-phase outlet flow exiting via the outlets of the plurality of microchannels. In implementations, the open areas enable the fluid inlet flow to spread laterally across the plurality of microchannels in a direction parallel to a heat transfer surface of the heat transfer matrix. In implementations, the manifold assembly further includes one or more manifold distribution layers, wherein each manifold distribution layer includes a plurality of liquid distribution areas in a region adjacent open areas in a manifold spacer layer to encourage the fluid inlet flow to distribute to all of the plurality of microchannels. In implementations, liquid distribution areas of a manifold distribution layer are offset from liquid distribution areas of another manifold distribution layer when manifold distribution layers are stacked together in the manifold assembly. In implementations, one or more of the open areas, the outlet passages, or the plurality of liquid distribution areas includes a flow restriction. In implementations, the manifold assembly further includes the input manifold configured to split the fluid inlet flow into a plurality of fluid inlet flows, each fluid inlet flow associated with a low power cooling portion of the plurality of microchannels, an intermediate manifold, the intermediate manifold configured to collect and mix two-phase output flow from each low power cooling portion, where mixing homogenizes local heating variations, and provide mixed two-phase output flow to a high power cooling portion of the plurality of microchannels, the output manifold configured to collect two-phase output flow from the high power cooling portion.

Described is a heat transfer matrix. In implementations, the heat transfer matrix includes a plurality of microchannels that are in fluid communication with a manifold for inputting flow to the plurality of microchannels and outputting two-phase flow from the plurality of microchannels, where each of the plurality of microchannels includes a flow restriction configured to inhibit redistribution of the flow and balance pressure drop between certain ones of the plurality of microchannels, and where pairs of the plurality of microchannels are in a counterflow configuration with an inlet of a microchannel adjacent to an outlet of a neighbor microchannel, the counterflow configuration increasing packing density and reducing pressure drop in the heat transfer matrix.

In implementations, the flow restriction is a reduction in cross-sectional area at each inlet of the plurality of microchannels. In implementations, each of the plurality of microchannels has an expanding microchannel geometry extending from the inlet configured with the flow restriction to the outlet. In implementations, a profile of the expanding microchannel geometry is based on at least one of flow rate, heat loading, and microchannel packing efficiency. In implementations, a profile of the expanding microchannel geometry is one of linear, piecewise linear, and hyperbolic. In implementations, the heat transfer matrix includes one or more stackable port layers configured to provide fluidic access from the manifold to inlets and outlets of the plurality of microchannels. In implementations, the heat transfer matrix includes one or more heat transfer channel layers, wherein each heat transfer channel layer includes a plurality of microchannels. In implementations, the plurality of microchannels constitute a microchannel array of thermal pixels, and where each thermal pixel is a pair of the plurality of microchannels in the counterflow configuration.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

Persons skilled in the art will understand that the various embodiments of the present disclosure and shown in the accompanying figures constitute non-limiting examples, and that additional components and features may be added to any of the embodiments discussed hereinabove without departing from the scope of the present disclosure. Additionally, persons skilled in the art will understand that the elements and features shown or described in connection with one embodiment may be combined with those of another embodiment without departing from the scope of the present disclosure to achieve any desired result and will appreciate further features and advantages of the presently disclosed subject matter based on the description provided. Variations, combinations, and/or modifications to any of the embodiments and/or features of the embodiments described herein that are within the abilities of a person having ordinary skill in the art are also within the scope of the present disclosure, as are alternative embodiments that may result from combining, integrating, and/or omitting features from any of the disclosed embodiments.

Use of the term “optionally” with respect to any element of a claim means that the element may be included or omitted, with both alternatives being within the scope of the claim. Additionally, use of broader terms such as “comprises,” “includes,” and “having” should be understood to provide support for narrower terms such as “consisting of,” “consisting essentially of,” and “comprised substantially of.” Accordingly, the scope of protection is not limited by the description set out above, but is defined by the claims that follow, and includes all equivalents of the subject matter of the claims.

In the preceding description, reference may be made to the spatial relationship between the various structures illustrated in the accompanying drawings, and to the spatial orientation of the structures. However, as will be recognized by those skilled in the art after a complete reading of this disclosure, the structures described herein may be positioned and oriented in any manner suitable for their intended purpose. Thus, the use of terms such as “above,” “below,” “upper,” “lower,” “inner,” “outer,” “left,” “right,” “upward,” “downward,” “inward,” “outward,” “horizontal,” “vertical,” etc., should be understood to describe a relative relationship between the structures and/or a spatial orientation of the structures. Those skilled in the art will also recognize that the use of such terms may be provided in the context of the illustrations provided by the corresponding figure(s).

Additionally, terms such as “approximately,” “generally,” “substantially,” and the like should be understood to allow for variations in any numerical range or concept with which they are associated and encompass variations on the order of 25% (e.g., to allow for manufacturing tolerances and/or deviations in design). For example, the term “generally parallel” should be understood as referring to configurations in with the pertinent components are oriented so as to define an angle therebetween that is equal to 180°±25% (e.g., an angle that lies within the range of (approximately) 135° to (approximately) 225°). The term “generally parallel” should thus be understood as referring to encompass configurations in which the pertinent components are arranged in parallel relation.

Although terms such as “first,” “second,” “third,” etc., may be used herein to describe various operations, elements, components, regions, and/or sections, these operations, elements, components, regions, and/or sections should not be limited by the use of these terms in that these terms are used to distinguish one operation, element, component, region, or section from another. Thus, unless expressly stated otherwise, a first operation, element, component, region, or section could be termed a second operation, element, component, region, or section without departing from the scope of the present disclosure.

Each and every claim is incorporated as further disclosure into the specification and represents embodiments of the present disclosure. Also, the phrases “at least one of A, B, and C” and “A and/or B and/or C” should each be interpreted to include only A, only B, only C, or any combination of A, B, and C.

What is claimed is:

1. A two-phase heat exchanger, comprising:
a manifold assembly configured to have an input manifold for fluid inlet flow and an output manifold for two-phase output flow; and
a heat transfer matrix coupled to the manifold assembly,
wherein the heat transfer matrix includes a plurality of microchannels that are in fluid communication with the input manifold and the output manifold,
wherein each of the plurality of microchannels includes a flow restriction configured to inhibit redistribution of fluid inlet flow and balance pressure drop between certain ones of the plurality of microchannels, and
wherein pairs of the plurality of microchannels are in a counterflow configuration with an inlet of a microchannel adjacent to an outlet of a neighbor microchannel, the counterflow configuration increasing packing density and reducing pressure drop in the heat transfer matrix.

2. The two-phase heat exchanger of claim 1, wherein the flow restriction is a reduction in cross-sectional area at each inlet of the plurality of microchannels.

3. The two-phase heat exchanger of claim 1, wherein each of the plurality of microchannels has an expanding microchannel geometry extending from the inlet configured with the flow restriction to the outlet.

4. The two-phase heat exchanger of claim 3, wherein a profile of the expanding microchannel geometry is based on at least one of flow rate, heat loading, and microchannel packing efficiency.

5. The two-phase heat exchanger of claim 3, wherein a profile of the expanding microchannel geometry is one of linear, piecewise linear, and hyperbolic.

6. The two-phase heat exchanger of claim 1, wherein the heat transfer matrix further comprises:
one or more stackable port layers configured to provide fluidic access from the manifold assembly to inlets and outlets of the plurality of microchannels; and
one or more heat transfer channel layers, wherein cach heat transfer channel layer includes a plurality of microchannels.

7. The two-phase heat exchanger of claim 1, wherein the manifold assembly further comprises:
one or more manifold spacer layers,
wherein each manifold spacer layer defines open areas for the fluid inlet flow to spread to inlets of the plurality of microchannels, and
wherein each manifold spacer layer defines outlet passages for the two-phase outlet flow exiting via the outlets of the plurality of microchannels.

8. The two-phase heat exchanger of claim 7, wherein the open areas enable the fluid inlet flow to spread laterally across the plurality of microchannels in a direction parallel to a heat transfer surface of the heat transfer matrix.

9. The two-phase heat exchanger of claim 7, wherein the manifold assembly further comprises:
one or more manifold distribution layers, wherein each manifold distribution layer includes a plurality of liquid distribution areas in a region adjacent open areas in a manifold spacer layer to encourage the fluid inlet flow to distribute to all of the plurality of microchannels.

10. The two-phase heat exchanger of claim 9, wherein liquid distribution areas of a manifold distribution layer are offset from liquid distribution areas of another manifold distribution layer when manifold distribution layers are stacked together in the manifold assembly.

11. The two-phase heat exchanger of claim 9, wherein one or more of the open areas, the outlet passages, or the plurality of liquid distribution areas includes a flow restriction.

12. The two-phase heat exchanger of claim 1, wherein the manifold assembly further comprises:
the input manifold configured to split the fluid inlet flow into a plurality of fluid inlet flows, cach fluid inlet flow associated with a low power cooling portion of the plurality of microchannels;
an intermediate manifold, the intermediate manifold configured to:
collect and mix two-phase output flow from each low power cooling portion, wherein mixing homogenizes local heating variations; and
provide mixed two-phase output flow to a high power cooling portion of the plurality of microchannels;
the output manifold configured to collect two-phase output flow from the high power cooling portion.

13. A heat transfer matrix, comprising:
a plurality of microchannels that are in fluid communication with a manifold for inputting flow to the plurality of microchannels and outputting two-phase flow from the plurality of microchannels,
wherein each of the plurality of microchannels includes a flow restriction configured to inhibit redistribution of the flow and balance pressure drop between certain ones of the plurality of microchannels, and
wherein pairs of the plurality of microchannels are in a counterflow configuration with an inlet of a microchannel adjacent to an outlet of a neighbor microchannel, the counterflow configuration increasing packing density and reducing pressure drop in the heat transfer matrix.

14. The heat transfer matrix of claim 13, wherein the flow restriction is a reduction in cross-sectional area at each inlet of the plurality of microchannels.

15. The heat transfer matrix of claim 14, wherein each of the plurality of microchannels has an expanding microchannel geometry extending from the inlet configured with the flow restriction to the outlet.

16. The heat transfer matrix of claim 15, wherein a profile of the expanding microchannel geometry is based on at least one of flow rate, heat loading, and microchannel packing efficiency.

17. The heat transfer matrix of claim 15, wherein a profile of the expanding microchannel geometry is one of linear, piecewise linear, and hyperbolic.

18. The heat transfer matrix of claim 13, further comprising:
one or more stackable port layers configured to provide fluidic access from the manifold to inlets and outlets of the plurality of microchannels.

19. The heat transfer matrix of claim 13, further comprising:
one or more heat transfer channel layers, wherein each heat transfer channel layer includes a plurality of microchannels.

20. The heat transfer matrix of claim 13, wherein the plurality of microchannels constitute a microchannel array of thermal pixels, and wherein each thermal pixel is a pair of the plurality of microchannels in the counterflow configuration.
